(19) United States
(12) Patent Application Publication
(10) Pub. No.: US 2021/0175075 A1
(43) Pub. Date: Jun. 10, 2021

(54) OXYGEN RADICAL ASSISTED DIELECTRIC FILM DENSIFICATION

(71) Applicant: APPLIED MATERIALS, INC., Santa Clara, CA (US)

(72) Inventors: SHASHANK SHARMA, FREMONT, CA (US); WEI LIU, SAN JOSE, CA (US); YONG SUN, San Jose, CA (US); PRAKET PRAKASH JHA, Sunnyvale, CA (US)

(21) Appl. No.: 16/708,026

(22) Filed: Dec. 9, 2019

(51) Int. Cl. H01L 21/02; H01L 21/3115; H01J 37/32

(52) U.S. Cl. CPC H01L 21/02323; H01L 21/3115; H01J 2237/336; H01L 21/0214; H01J 37/32357; H01L 21/02337

(57) ABSTRACT

Embodiments herein provide for oxygen radical based treatment of silicon containing material layers deposited using a flowable chemical vapor deposition (FCVD) process. Oxygen radical based treatment of the FCVD deposited silicon containing material layers desirably increases the number of stable Si—O bonds, removes undesirably hydrogen and nitrogen impurities, and provides for further densification and excellent film quality in the treated silicon containing material layers. Embodiments include methods and apparatus for making a semiconductor device including: contacting a flowable layer of silicon containing material disposed on a substrate with a plurality of oxygen radicals under conditions sufficient to anneal and increase the density of the flowable layer of silicon containing material.

### FIELD

Embodiments of the present disclosure generally relate to the field of electronic device manufacturing and modifying a property of a dielectric layer.

### BACKGROUND

Dielectric materials are broadly used in the semiconductor industry to produce electronic devices of an ever-decreasing size. Generally, the dielectric materials are used as gap-fill films, shallow trench insulations (STI), via fills, masks, gate dielectrics, or as other electronic device features.

Dielectric materials typically include silicon containing materials such as silicon dioxide (SiO₂) and may be formed from precursors into a flowable material using a flowable chemical vapor deposition (FCVD) process. Flowable silicon containing materials processes, e.g., silicon containing material layers deposited using a (FCVD) process, generally provide for improved gap fill performance of high aspect ratio features when compared to silicon containing material layers deposited using conventional methods. However, the inventors have found that silicon containing material layers typically provided by an FCVD process problematically include Si—H, Si—NH bonds and carbon bonds leading to lower or poor silicon oxide layer film density when forming silicon oxide materials.

While flowable silicon containing material may be further treated after deposition thereof, the inventors have found that treatment methods create a risk of damaging underlying features and materials on the substrate due to ion bombardment or are otherwise inadequate for treating silicon containing materials disposed in high aspect ratio openings. For example, high temperature anneals may induce film shrinkage and stress resulting in cracking, peeling of the film, or both, hindering the dielectric film formation in deep trench and via fill applications.

Accordingly, what is needed are improved methods of treating a deposited flowable silicon containing material to achieve a desired density and/or other desired material properties.

### SUMMARY

Methods and apparatus for making a semiconductor device including treating a flowable silicon containing material are provided herein. In some embodiments, a method of making a semiconductor device includes: contacting a flowable layer of silicon containing material disposed on a substrate with a plurality of oxygen radicals under conditions sufficient to anneal and increase a density of the flowable layer of silicon containing material.

In some embodiments, a method of making a semiconductor device includes: depositing a flowable layer of silicon containing material over one or more features over a substrate; and implanting or incorporating oxygen radicals substantially throughout the flowable layer of silicon containing material to anneal and increase a density of the flowable layer of silicon containing material.

In some embodiments, an apparatus to manufacture an electronic device includes: a processing chamber including a pedestal to hold a substrate including a flowable layer of silicon containing material over the substrate; an oxygen radical source coupled to the processing chamber; and a processor coupled to the process chamber and the oxygen radical source, wherein the processor is configured to provide conditions in the processing chamber sufficient to anneal and increase a density of the flowable layer of silicon containing material.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 is a schematic cross-sectional view of a processing chamber for use in methods of the present disclosure.

FIG. 2A is a side view of a semiconductor substrate for treatment in accordance with the present disclosure.

FIG. 2B is a side view of a flowable layer deposited over the features of the semiconductor substrate according to embodiments of the present disclosure.

FIG. 2C shows oxygen radicals contacting the flowable layer according to embodiments of the present disclosure.

FIG. 2D shows implanting or incorporating oxygen radicals into the flowable layer according to embodiments of the present disclosure.

FIG. 3 is a flow diagram of making a semiconductor device in accordance with some embodiments of the present disclosure.

FIG. 4 is a flow diagram an embodiment of making a semiconductor device in accordance with some embodiments of the present disclosure.

FIG. 5 is a perspective view of a tri-gate transistor structure according to one embodiment of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments described herein generally relate to methods for oxygen radical based treatment of silicon containing material layers disposed on a substrate surface, for example, to methods for oxygen radical based treatment of silicon containing material layers which have been deposited using a flowable chemical vapor deposition (FCVD) process. Flowable silicon containing material processes, such as e.g., silicon oxide layers deposited using a (FCVD) process, generally provide for improved gap fill performance of high aspect ratio features when compared to silicon containing material layers deposited using conventional methods. However, the inventors have found that contacting a flowable layer of silicon containing material with a plurality of oxygen radicals may be performed under conditions sufficient to anneal and increase a density of the flowable layer of silicon containing material. The oxygen radicals are reactive and suitable for deep penetration of the flowable layer of silicon containing material leading to improved film quality by the reduction or elimination of Si—H, Si—NH, or carbon bonds. Further the inventors have observed that the risk of damaging underlying features and materials on the substrate due to conventional treatments such as ion bombardment or high temperature anneals resulting in film shrinkage and stress may be reduced or eliminated.

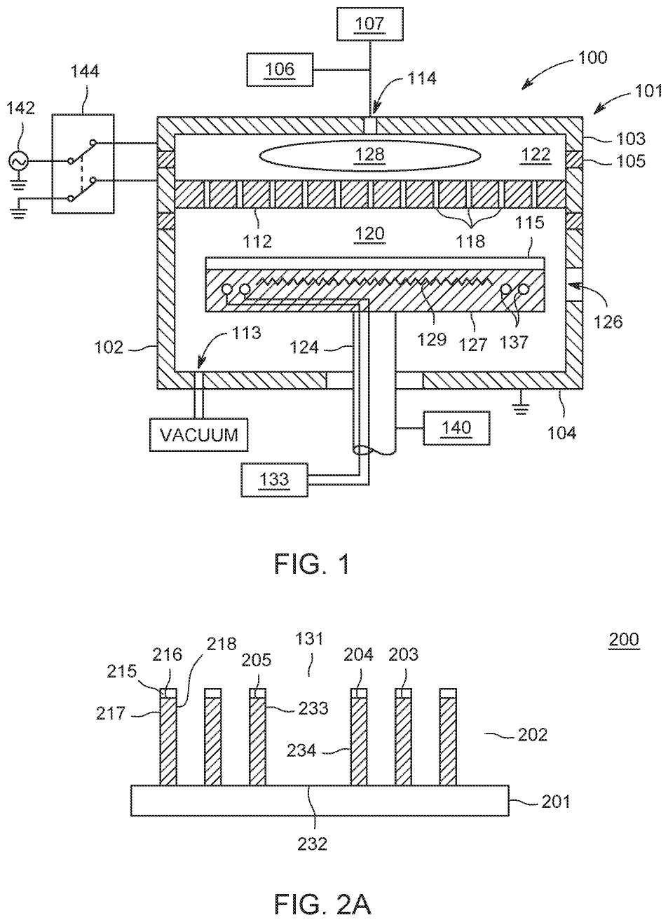

FIG. 1 is a schematic cross-sectional view of a processing chamber suitable for use in methods of the present disclosure. In some embodiments, the processing chamber 100 includes a chamber lid assembly 101, one or more sidewalls 102, and a chamber base 104 which collectively define a processing volume 120. The chamber lid assembly 101 includes a chamber lid 103, a showerhead 112, and an electrically insulating ring 105, disposed between the chamber lid 103 and the showerhead 112, which define a plenum 122. A gas inlet 114, disposed through the chamber lid 103 is fluidly coupled to a gas source 106. In some embodiments, the gas inlet 114 is further fluidly coupled to a remote plasma source 107. The showerhead 112, having a plurality of openings 118 disposed therethrough, is used to uniformly distribute processing gases or oxygen radicals from the plenum 122 into the processing volume 120 through the plurality of openings 118.

In some embodiments, a power supply 142, such as an RF or VHF power supply, is electrically coupled to the chamber lid via a switch 144 when the switch is disposed in a first position (as shown). When the switch is disposed in a second position (not shown) the power supply 142 is electrically coupled to the showerhead 112. When the switch 144 is in the first position, the power supply 142 is used to ignite and maintain a first plasma which is remote from the substrate 115, such as the remote plasma 128 disposed in the plenum 122. The remote plasma 128 is composed of the processing gases flowed into the plenum and maintained as a plasma by the capacitive coupling of the power from the power supply 142 therewith. When the switch 144 is in the second position, the power supply 142 is used to ignite and maintain a second plasma (not shown) in the processing volume 120 between the showerhead 112 and the substrate 115 disposed on the substrate support 127.

In some embodiments, the processing volume 120 is fluidly coupled to a vacuum source, such as to one or more dedicated vacuum pumps, through a vacuum outlet 113 which maintains the processing volume 120 at sub-atmospheric conditions and evacuates the processing and other gases therefrom. A substrate support 127, disposed in the processing volume 120, is disposed on a support shaft 124 sealingly extending through the chamber base 104, such as being surrounded by bellows (not shown) in the region below the chamber base 104. The support shaft 124 is coupled to a controller 140 that controls a motor to raise and lower the support shaft 124, and the substrate support 127 disposed thereon, to support a substrate 115 during processing thereof, and to transfer of the substrate 115 to and from the processing chamber 100.

The substrate 115 is loaded into the processing volume 120 through an opening 126 in one of the one or more sidewalls 102, which is conventionally sealed with a or door or a valve (not shown) during substrate 115 processing. Herein, the substrate 115 is transferred to and from the surface of the substrate support 127 using a conventional lift pin system (not shown) comprising a plurality of lift pins (not shown) movably disposed through the substrate support. Typically, the plurality of lift pins are contacted from below by a lift pin hoop (not shown) and moved to extend above the surface of the substrate support 127 lifting the substrate 115 therefrom and enabling access by a robot handler. When the lift pin hoop (not shown) is in a lowered position the tops of the plurality of lift pins are located to be flush with, or below, the surface of the substrate support 127 and the substrate rests thereon. The substrate support is moveable between a lower position, below the opening 126, for placement of a substrate thereon or removal of a substrate 115 therefrom, and a raised position for processing of the substrate 115. In some embodiments, the substrate support 127, and the substrate 115 disposed thereon, are maintained at a desired processing temperature using a resistive heating element 129 and/or one or more cooling channels 137 disposed in the substrate support. Typically, the cooling channels 137 are fluidly coupled to a coolant source 133 such as a modified water source having relatively high electrical resistance or a refrigerant source. In some embodiments, the substrate is disposed within a rapid thermal processing chamber where lamps are configured to rapidly heat the substrate. In some embodiments, the rapid thermal processing chamber is configured for performing methods in accordance with the present disclosure such as contacting a flowable layer of silicon containing material disposed on a substrate with a plurality of oxygen radicals under conditions sufficient to anneal and increase a density of the flowable layer of silicon containing material. Non-limiting examples of a rapid thermal process chamber suitable for configuration in accordance with the present disclosure include processing chambers suitable for heating the substrate to a predetermined temperature in a short period of time. In some embodiments, the heating system includes a light source disposed so that light energy emitted by the light source such as from a lamp contacts and heats the material surface of the substrate. In some embodiments the substrate is disposed within a process chamber, such as the CENTURA® RADIANCE® RTP chamber available from Applied Materials, Inc., located in Santa Clara, Calif. and exposed to an anneal process in accordance with the present disclosure. In embodiments, the anneal chamber may be configured such that the substrate may be annealed without being exposed to the ambient environment.

In some embodiments, the processing chamber 100 is further coupled to a remote plasma source 107 which provides oxygen radicals to the processing volume 120. Typically, the remote plasma source (RPS) includes an inductively coupled plasma (ICP) source, a capacitively coupled plasma (CCP) source, or a microwave plasma source. In some embodiments, the remote plasma source is a standalone RPS unit. In other embodiments, the remote plasma source is a second processing chamber in fluid communication with the processing chamber 100. In other embodiments, the remote plasma source is the remote plasma 128 ignited and maintained in the plenum 122 between the chamber lid 103 and the showerhead 112. In some other embodiments, gaseous treatment radicals are provided to the processing chamber from a non-plasma based radical source, such as a UV source which uses UV radiation to photo-dissociate the first gas into the radical species thereof or a hot wire source, such as a hot wire CVD (HWCVD) chamber which uses thermal decomposition to dissociate the first gas into its radical species.

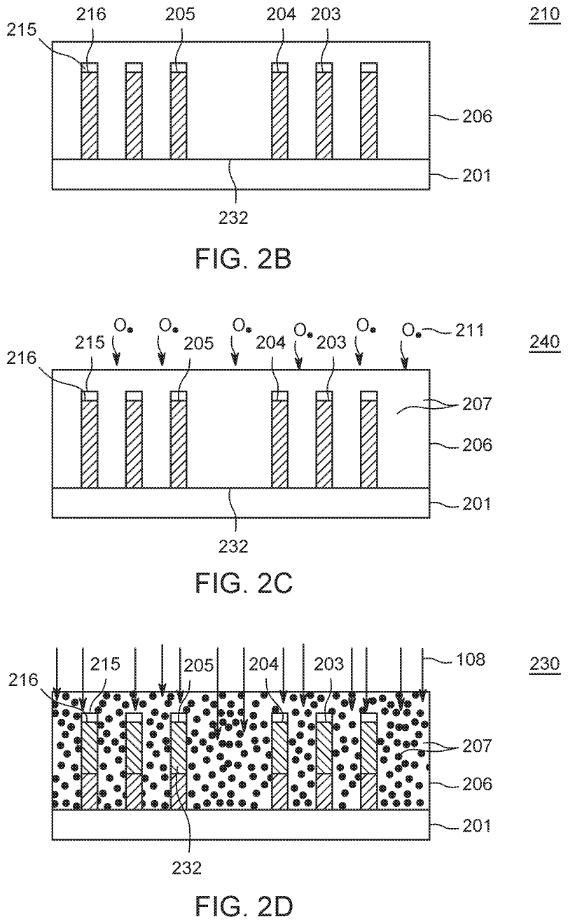

FIG. 2A is a side view of an electronic device structure 200 in accordance with the present disclosure. In embodiments, electronic device structure 200 includes a substrate 201. In some embodiments, substrate 201 includes a semiconductor material, e.g., silicon (Si), germanium (Ge), silicon germanium (SiGe), a III-V material based material, or any combination thereof. In one embodiment, substrate 201 includes metallization interconnect layers for integrated circuits. In one embodiment, substrate 201 includes electronic devices, e.g., transistors, memories, capacitors, resistors, optoelectronic devices, switches, and any other active and passive electronic devices that are separated by an electrically insulating layer, for example, an interlayer dielectric, a trench insulation layer, or any other insulating layer known to one of ordinary skill in the art of the electronic device manufacturing. In at least some embodiments, substrate 201 includes interconnects, for example, vias, configured to connect the metallization layers. In one embodiment, substrate 201 is a semiconductor-on-isolator (SOI) substrate including a bulk lower substrate, a middle insulation layer, and a top monocrystalline layer. The top monocrystalline layer may comprise any material listed above, e.g., silicon.

In some embodiments, a device layer 202 is deposited on substrate 201. In some embodiments, device layer 202 includes a plurality of features, such as features 203, 204 and 205. As shown in FIG. 2A, a plurality of trenches, such as a trench 131 are formed on substrate 201 between the features. In embodiments, the trench has a bottom portion 232 and opposing sidewalls 233 and 234. Bottom portion 232 is an exposed portion of the substrate 201 between the features 204 and 205. A sidewall 233 is the sidewall of the feature 205, and a sidewall 234 is the sidewall of the feature 204. In some embodiments, the device layer 202 includes one or more semiconductor fins formed on the substrate 201. In some embodiments, the features, e.g., 203, 204 and 205 are fin structures to form, for example, a tri-gate transistor array including multiple transistors, such as a tri-gate transistor (transistor 500) shown in FIG. 5.

In some embodiments, the height of the features 203, 204 and 205 is in an approximate range from about 30 nm to about 500 nm (nanometer). In some embodiments, the distance between the features 203 and 204 is from about 2 nm to about 100 nm.

In some embodiments, device layer 202 includes one or more layers deposited on substrate 201 using one or more deposition techniques, such as but not limited to a chemical vapor deposition (CVD), e.g., a plasma enhanced chemical vapor deposition (PECVD), a physical vapor deposition (PVD), molecular beam epitaxy (MBE), metalorganic chemical vapor deposition (MOCVD), atomic layer deposition (ALD), or other deposition techniques known to one of ordinary skill in the art of electronic device manufacturing. In some embodiments, the one or more layers of the device layer 202 are patterned and etched using patterning and etching techniques known to one of ordinary skill in the art of electronic device manufacturing to form features, such as features 203, 204 and 205. In an embodiment, each of the features of the device layer 202 is a stack of one or more layers. In an embodiment, the features of the device layer 202 are features of electronic devices, e.g., transistors, memories, capacitors, resistors, optoelectronic devices, switches, and any other active and passive electronic devices.

In some embodiments, the features of the device layer 202 includes a conductive layer. In an embodiment, the features of the device layer 202 comprise a metal, for example, copper (Cu), aluminum (Al), indium (In), tin (Sn), lead (Pb), silver (Ag), antimony (Sb), bismuth (Bi), zinc (Zn), cadmium (Cd), gold (Au), ruthenium (Ru), nickel (Ni), cobalt (Co), chromium (Cr), iron (Fe), manganese (Mn), titanium (Ti), hafnium (Hf), tantalum (Ta), tungsten (W), vanadium (V), molybdenum (Mo), palladium (Pd), gold (Au), platinum (Pt), polysilicon, other conductive layer known to one of ordinary skill in the art of electronic device manufacturing, or any combination thereof.

As shown in FIG. 2A, a protection layer 215 is optionally deposited over the features of the device layer 202. In embodiments, the protection layer 215 covers top portions, such as a top portion 216 of each of the features of the device layer 202, as shown in FIG. 2A. In some embodiments, the protection layer 215 is deposited to protect the features of the device layer 202 from processing at a later stage. In some embodiments, the features of the device layer 202 are silicon features. In some embodiments, the protection layer 215 is a hard mask layer. In some embodiments, the protection layer covers the top portions and sidewalls, such as a sidewall 217 and a sidewall 218 of each of the features of the device layer 202. In some embodiments, the protection layer 215 is a nitride layer, e.g., silicon nitride, titanium nitride, an oxide layer, e.g., a boron oxide layer, a boron doped glass layer, a silicon oxide layer, other protection layer, or any combination thereof. In some embodiment, the thickness of the protection layer 215 is from about 2 nm to about 50 nm.

In some embodiments, the protection layer 215 can be deposited using one or more deposition techniques, such as but not limited to a chemical vapor deposition (CVD), e.g., a Plasma Enhanced Chemical Vapor Deposition (PECV”), a physical vapor deposition (PVD), molecular beam epitaxy (MBE), metalorganic chemical vapor deposition (MOCVD), atomic layer deposition (ALD), or other deposition techniques known to one of ordinary skill in the art of electronic device manufacturing.

FIG. 2B shows a side view of an electronic device structure 210 in accordance with the present disclosure. In embodiments, electronic device structure 210 includes a substrate 201. FIG. 2B shows a device after a flowable layer 206 is deposited over the features of the device layer 202. In some embodiments, flowable layer 206 covers optional protection layer 215 deposited on top portions, sidewalls of the features of the device layer and bottom portions of the trenches, such as bottom portion 232. In some embodiments, flowable layer 206 is deposited directly on the top portions and sidewalls of the features of the device layer 202 without protection layer 215. In some embodiments, flowable layer 206 is deposited on portions of the substrate 201 filling in the space between the features of the device layer 202. In an embodiment, flowable layer 206 is a dielectric layer. In some embodiments, the as deposited density of the flowable layer 206 is e.g., less than or about 1.5 g/cm³. In some embodiments, the density of the flowable layer 206 is increased by the methods of the present disclosure such as to an amount greater than 1.5 g/cm³. Generally, the density of a material refers to the mass of the material per unit volume (mass divided by volume). In some embodiments, flowable layer 206 has pores (not shown). In some embodiments, pores in the material refer to regions which contain something other than the considered material (e.g., air, vacuum, liquid, solid, or a gas or gaseous mixture) so that the density of the flowable layer varies depending on location.

In some embodiments, flowable layer 206 is an oxide layer, e.g., silicon oxide (e.g., SiO₂), aluminum oxide (Al₂O₃), or other oxide layer, a nitride layer, e.g., silicon nitride (e.g., Si₃N₄), or other nitride layer, a carbide layer (e.g., carbon, SiOC), or other carbide layer, an oxide nitride layer, (e.g., SiON), or any combination thereof.

In some embodiments, flowable layer 206 is a flowable CVD film developed as a flowable layer of silicon containing material, wherein as-deposited film typically contains Si—H, Si—N, and —NH bonds. The film is then converted in an oxidizing environment to Si—O network through curing and annealing in accordance with the present disclosure.

In an embodiment, flowable layer 206 is deposited using one or more flowable chemical vapor deposition (FCVD) deposition techniques developed by Applied Materials, Inc. located in Santa Clara, Calif., or other FCVD deposition techniques known to one of ordinary skill in the art of electronic device manufacturing. In some embodiments, the thickness of the flowable layer 206 is from about 30 nm to about 500 nm. In some embodiments, the thickness of the flowable layer 206 is from about 40 nm to about 100 nm.

In some embodiments, the flowable layer 206 acts as a gap fill layer. In some embodiments, flowable layer 206 acts as a gap fill layer over one portion of substrate and acts as hard mask layer over other portion of substrate. In some embodiments, flowable layer 206 acts as a gap fill layer in a high-aspect ratio (height to width) feature such as 5:1 or 20:1, wherein the feature has a width less than 20 nanometer.

Referring now to FIG. 2C, oxygen radicals (O.) 211 contact flowable layer 206 according to some embodiments of the present disclosure. In some embodiments, a flowable layer of silicon containing material disposed on a substrate is contacted with a plurality of oxygen radicals such as radicals (O.) 211 under conditions sufficient to anneal and/or increase a density of the flowable layer of silicon containing material. Non-limiting silicon containing material include an oxide layer, a nitride layer, a carbide layer, an oxynitride layer, or combinations thereof. In some embodiments, the flowable layer of silicon containing material comprises silicon oxide (SiO₂), silicon oxide nitride (SiON), silicon nitride (Si₃N₄), or silicon oxide carbide (SiOC). In some embodiments, the flowable layer of silicon containing material is contacted with the plurality of oxygen radicals at a pressure of 10 mTorr to 20 Torr. In some embodiments, the flowable layer of silicon containing material is contacted with a plurality of oxygen radicals at a temperature of 100 degrees Celsius to 700 degrees Celsius. In some embodiments, a flowable layer of silicon containing material is contacted with a plurality of oxygen radicals for a duration of up to 10 minutes such as 10 seconds to 10 minutes. In some embodiments, the plurality of oxygen radicals penetrate through a top portion and bottom portion of the flowable layer of silicon containing material and are incorporated into the flowable layer of silicon containing material. In some embodiments, the flowable layer 206 is oxidized by oxygen radical (O.) to form insulating regions between the features of the device layer 202. In an embodiment, the flowable layer 206 is treated by oxygen radical (O.) to form shallow trench insulation (STI) regions. In some embodiments, the flowable layer 206 of silicon containing material is disposed on a substrate 201 with a plurality of oxygen radicals such as oxygen radical (O.) 211 under conditions sufficient to anneal and increase a density of the flowable layer of silicon containing material.

In some embodiments, the plurality of oxygen radicals are disposed within a reaction gas, wherein the reaction gas comprises one or more of oxygen (O₂), hydrogen (H₂) or nitrogen (N₂). For example, the reaction gas may comprise a mixture of hydrogen mixed with oxygen or hydrogen mixed with nitrogen. In embodiments, the reaction gas comprising oxygen radicals may further comprise up to 95% hydrogen.

Referring to FIG. 2D, implanting a plurality of oxygen radicals such as oxygen radical (O.) 211 to the flowable layer 206 according to embodiments of the present disclosure is shown. A plurality of oxygen radicals such as oxygen radical (O.) 211 are supplied to the flowable layer 206, as shown in FIG. 2D. In some embodiments, a plurality of oxygen radicals such as oxygen radical (O.) 211 includes only oxygen radicals. In embodiments, a plurality of oxygen radicals such as oxygen radical (O.) 211 penetrate or are incorporated into a ⅓ portion, top half, or top ⅔ portion of the flowable layer 206. In some embodiments, as a plurality of oxygen radicals such as oxygen radical (O.) 211 are supplied under conditions sufficient to penetrate throughout all of the flowable layer 206. In some embodiments, a plurality of oxygen radicals such as oxygen radical (O.) 211 are supplied under conditions sufficient to implant and be incorporated throughout all of the flowable layer 206.

In some embodiments, as a plurality of oxygen radicals such as oxygen radical (O.) 211 are supplied in an amount sufficient to increase the density of the flowable layer 206. In some embodiments, oxygen radical (O.) 211 are supplied in an amount sufficient and under conditions suitable to increase the density of the flowable layer 206. In some embodiments, the density is measurable by known techniques in the art including proxies such as wet etch rate ratio (WERR) indicative of changes in density. In some embodiments, in accordance with the present disclosure a treated flowable layer of silicon containing material is formed and has a wet etch rate ratio (WERR) in dilute HF of about 9, or about 10, or between about 9-10 after an etch duration of 0-2 minutes. In embodiments, the wet etch rate ratio is measured relative to a thermal silicon oxide film using dilute HF (e.g., 1:100 HF).

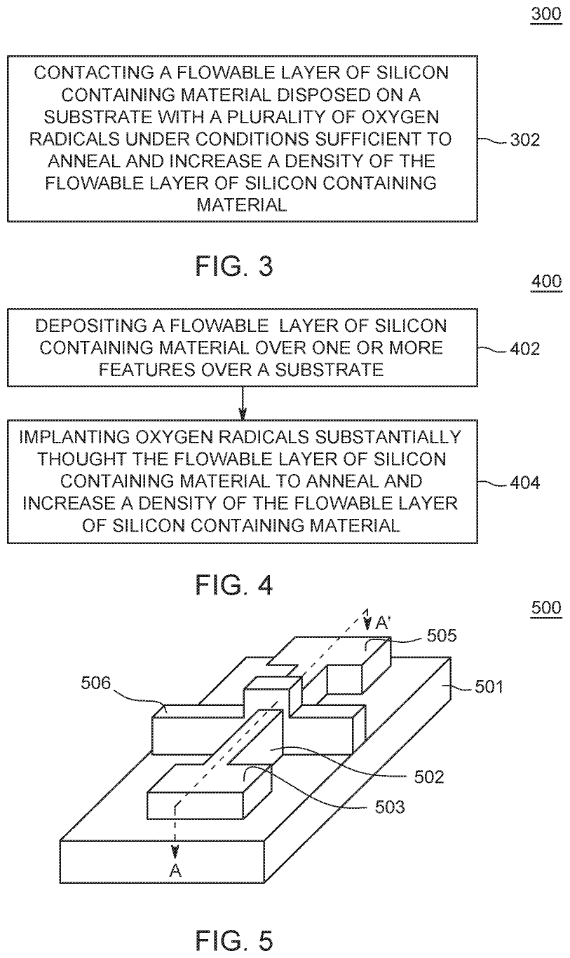

Referring now to FIG. 3, a flow diagram of a method of making a semiconductor device in accordance with some embodiments of the present disclosure is shown. In embodiments, the method 300 includes process sequence 302 including contacting a flowable layer of silicon containing material disposed on a substrate with a plurality of oxygen radicals under conditions sufficient to anneal and/or increase a density of the flowable layer of silicon containing material. In some embodiments the method includes contacting a silicon nitride layer with gaseous oxygen radicals. Although not shown in method 300, the method may optionally include positioning a substrate on a substrate support, where the substrate support is disposed in a processing volume of a processing chamber, such as the processing chamber described in FIG. 1. In some embodiments, the substrate features a silicon nitride layer deposited on a surface thereof. In some embodiments, contacting the flowable layer of silicon containing material with the plurality of oxygen radicals is at a pressure of 10 mTorr to 20 Torr, at a temperature of 100 degrees Celsius to 700 degrees Celsius for a duration of up to 10 minutes. In embodiments, the plurality of oxygen radicals are applied under amounts and conditions suitable to penetrate through a top portion and to the bottom portion of the flowable layer of silicon containing material. In some embodiments, contacting a flowable layer of silicon containing material with a plurality of oxygen radicals is performed in a rapid thermal processing chamber. In some embodiments, the plurality of oxygen radicals are disposed within a reaction gas, wherein the reaction gas comprises one or more of oxygen, hydrogen, nitrogen, or combinations thereof.

In some embodiments, the silicon containing material is at least partially disposed in a plurality of openings formed in the surface of the substrate. In some embodiments, the plurality of openings have an aspect ratio (depth to width ratio) of more than 2:1, such as more than 5:1, more than 10:1, more than 20:1, for example more than 25:1. In some embodiments, the width of the openings is less than about 22 nm, for example less than about 16 nm, or between about 1 nm and about 20 nm, such as between about 10 nm and about 20 nm.

Referring now to FIG. 4, a flow diagram of a method 400 of making a semiconductor device in accordance with some embodiments of the present disclosure is shown. At process sequence 402, a flowable layer of silicon containing material is deposited over one or more features over a substrate. In some embodiments, a silicon nitride layer, e.g., a polysilazane layer, is deposited using a flowable chemical vapor deposition (FCVD) process. In some embodiments, the FCVD process is performed in the same processing chamber used for the radical based treatment of the silicon containing material layer. In some embodiments, the FCVD process is performed in a processing chamber which is different from the processing chamber used for the radical based treatment of the silicon containing material.

In some embodiments, process sequence 402 may include an FCVD process such as flowing one or more silicon precursors into the processing volume, exposing the substrate to the one or more silicon precursors, providing one or more co-reactants in the processing volume, and exposing the substrate to the one or more co-reactants. In some embodiments, exposing the substrate to one or more silicon precursors and exposing the substrate to the one or more co-reactants is done sequentially, concurrently, or a combination thereof.

In some embodiments, FCVD is performed wherein the pressure of the processing volume is desirably maintained at between about 10 mTorr and about 10 Torr, such as less than about 6 Torr, such as less than about 5 Torr, or between about 0.1 Torr and about 4 Torr, such as between about 0.5 Torr and about 3 Torr. In some embodiments, the substrate is desirably maintained at a temperature between about 0 degrees Celsius and about 400 degrees Celsius, or less than about 200 degrees Celsius or between about −10 degrees Celsius and about 75 degrees Celsius.

In some embodiments, the one or more silicon precursors comprise a silane compound, such as silane (SiH₄), disilane (Si₂H₆), trisilane (Si₃H₆), and tetrasilane (Si₄H₁₀), or combinations thereof. In some other embodiments, the silicon precursor comprises a silazane compound having at least one Si—N—Si functional group, such as N,N′ disilyltrisilazane (A), other silazane compounds such as silazane compounds, such as for example trisilylamine (TSA), or combinations thereof. In some embodiments, the silicon precursor comprises a combination of one or more silane compounds and one or more silazane compounds.

In some FCVD embodiments, a capacitively coupled plasma is formed from a gas which is ignited and maintained in the processing volume between a showerhead and a chamber lid, such as the remote plasma 128 ignited and maintained in the plenum 122 described in FIG. 1. In some embodiments, the FCVD process described above desirably provides a flowable silicon oxide or nitride film that enables the bottom up filling of high aspect ratio openings formed in the surface of the substrate. For example, the FCVD process may be used to fill openings having a width less than 20 nm and an aspect ratio of more than about 10:1. In some embodiments, the substrate is maintained at a temperature below about 200 degrees Celsius.

At process sequence 404, method 400 includes implanting oxygen radicals substantially through the flowable layer of silicon containing material to anneal and/or increase the density of the flowable layer of silicon containing material. In some embodiments, process sequence 404 includes exposing the FCVD deposited silicon flowable layer to oxygen radicals to form a treated silicon layer. In some embodiments, FCVD depositing the silicon layer and exposing the FCVD deposited silicon layer to the oxygen radicals are done in the same processing chamber.

In some embodiments, the method 400 includes sequential repetitions of depositing at least part of the flowable layer of silicon containing material and then the oxygen radical based treatment of the at least partially deposited silicon containing material until a desired silicon containing material thickness is reached. Typically, the sequential repetitions facilitate more uniform densification and stoichiometry of the resulting treated silicon containing material when compared to depositing a silicon containing material to the desired thickness followed by the radical based treatment thereof.

In some embodiments, the present disclosure relates to a method of making a semiconductor device including: contacting a flowable layer of silicon containing material disposed on a substrate with a plurality of oxygen radicals under conditions sufficient to anneal and increase a density of the flowable layer of silicon containing material. In some embodiments, the flowable layer of silicon containing material comprises an oxide layer, a nitride layer, a carbide layer, or an oxynitride layer. In some embodiments, the flowable layer of silicon containing material comprises silicon oxide (SiO₂), silicon oxide nitride (SiON), silicon nitride (Si₃N₄), or silicon oxide carbide (SiOC). In some embodiments, contacting the flowable layer of silicon containing material with the plurality of oxygen radicals is at a pressure of 10 mTorr to 20 Torr. In some embodiments, contacting a flowable layer of silicon containing material with a plurality of oxygen radicals is at a temperature of 100 degrees Celsius to 700 degrees Celsius. In some embodiments, contacting a flowable layer of silicon containing material with a plurality of oxygen radicals is for a duration of up to 10 minutes. In some embodiments, the plurality of oxygen radicals penetrate through a top portion and bottom portion of the flowable layer of silicon containing material. In some embodiments, contacting a flowable layer of silicon containing material with a plurality of oxygen radicals is performed in a rapid thermal processing chamber. In some embodiments, prior to contacting the flowable layer of silicon containing material with a plurality of oxygen radicals the flowable layer of silicon containing material is contacted with ozone and water.

Referring now to FIG. 5, a perspective view of a tri-gate transistor structure according to one embodiment of the present disclosure is shown. In some embodiments a fin layer including a fin 502 is formed on a substrate 501. In some embodiments, fin layer represents a cross-sectional view of the fin 502 along A-A1 axis. In an embodiment, tri-gate transistor (transistor 500) is a part of a tri-gate transistor array that includes multiple tri-gate transistors. In some embodiments, a flowable dielectric layer modified by implanting oxygen radical species is formed on substrate 501 adjacent to fin 502 to provide field isolation (e.g., STI) regions that isolate one electronic device from other devices on substrate 501, as described above with respect to FIGS. 2A-2D. In some embodiments, the fin 502 protrudes from a top face of the substrate 501. Fin 502 can be formed of any well-known semiconductor material. In some embodiments, a gate dielectric layer (not shown) is deposited on and three sides of the fin 502. In some embodiments, the gate dielectric layer is formed on the opposing sidewalls and on the top surface of the fin 502. As shown in FIG. 5, a gate electrode 506 is deposited on the gate dielectric layer on the fin 502. Gate electrode 506 is fanned on and around the gate dielectric layer on the fin 502 as shown in FIG. 5. In some embodiments, a drain region 505 and a source region 503 are formed at opposite sides of the gate electrode 506 in fin 502, as shown in FIG. 5.

In some embodiments, the present disclosure relates to a method of making a semiconductor device including: depositing a flowable layer of silicon containing material over one or more features over a substrate; and implanting or incorporating oxygen radicals substantially throughout the flowable layer of silicon containing material to anneal and increase a density of the flowable layer of silicon containing material. In some embodiments, the flowable layer of silicon containing material comprises silicon oxide (SiO₂), silicon oxide nitride (SiON), silicon nitride (Si₃N₄), silicon oxide carbide (SiOC), or combinations thereof. In some embodiments, implanting oxygen radicals performed at a pressure of 10 mTorr to 20 Torr. In some embodiments, implanting oxygen radicals is performed at a temperature of 100 degrees Celsius to 700 degrees Celsius. In some embodiments, implanting oxygen radicals is performed for a duration of up to 10 minutes. In some embodiments, the oxygen radicals penetrate entirely throughout the flowable layer of silicon containing material. In some embodiments, implanting oxygen radicals into a flowable layer of silicon containing material is performed in a rapid thermal processing chamber. In some embodiments, prior to implanting oxygen radicals into a flowable layer of silicon containing material the flowable layer of silicon containing material is contacted with ozone and water.

In some embodiments, the present disclosure relates to an apparatus to manufacture an electronic device including: a processing chamber including a pedestal to hold a substrate including a flowable layer of silicon containing material over the substrate; an oxygen radical source coupled to the processing chamber; and a processor coupled to the oxygen radical source, wherein the processor is configured to provide conditions in the processing chamber sufficient to anneal and increase a density of the flowable layer of silicon containing material. In some embodiments, the flowable layer of silicon containing material includes silicon oxide (SiO₂), silicon oxide nitride (SiON), silicon nitride (Si₃N₄), silicon oxide carbide (SiOC), or combinations thereof. In some embodiments, the conditions include a pressure of 10 mTorr to 20 Torr, a temperature of 100 degrees Celsius to 700 degrees Celsius for a duration of up to 10 minutes.

In some embodiments, the present disclosure relates to a non-transitory computer readable medium having instructions stored thereon that, when executed, cause a process chamber to perform a method for making a semiconductor device including: contacting a flowable layer of silicon containing material disposed on a substrate with a plurality of oxygen radicals under conditions sufficient to anneal and increase a density of the flowable layer of silicon containing material.

In some embodiments, the present disclosure relates to a method for treating a flowable layer of silicon containing material including: contacting a flowable layer of silicon containing material disposed on a substrate with a plurality of oxygen radicals under conditions sufficient to anneal and increase a density of the flowable layer of silicon containing material.

In some embodiments, the present disclosure relates to a non-transitory computer readable medium having instructions stored thereon that, when executed, cause a process chamber to perform a method for treating a flowable layer of silicon containing material including: contacting a flowable layer of silicon containing material disposed on a substrate with a plurality of oxygen radicals under conditions sufficient to anneal and increase a density of the flowable layer of silicon containing material.

While the foregoing is directed to embodiments of the present disclosure, other and further embodiments of the disclosure may be devised without departing from the basic scope thereof.

1. A method of making a semiconductor device comprising:
contacting a flowable layer of silicon containing material disposed on a substrate with a plurality of oxygen radicals under conditions sufficient to anneal and increase a density of the flowable layer of silicon containing material.

2. The method of claim 1, wherein the flowable layer of silicon containing material comprises an oxide layer, a nitride layer, a carbide layer, an oxynitride layer, or combinations thereof.

3. The method of claim 2, wherein the flowable layer of silicon containing material comprises silicon oxide (SiO₂), silicon oxide nitride (SiON), silicon nitride (Si₃N₄), silicon oxide carbide (SiOC), or combinations thereof.

4. The method of claim 1, wherein contacting the flowable layer of silicon containing material with the plurality of oxygen radicals is at a pressure of 10 mTorr to 20 Torr.

5. The method of claim 1, wherein contacting a flowable layer of silicon containing material with a plurality of oxygen radicals is at a temperature of 100 degrees Celsius to 700 degrees Celsius.

6. The method of claim 1, wherein contacting a flowable layer of silicon containing material with a plurality of oxygen radicals is for a duration of up to 10 minutes.

7. The method of claim 1, wherein the plurality of oxygen radicals penetrate through a top portion and bottom portion of the flowable layer of silicon containing material.

8. The method of claim 1, wherein contacting a flowable layer of silicon containing material with a plurality of oxygen radicals is performed in a rapid thermal processing chamber.

9. The method of claim 1, wherein the plurality of oxygen radicals are disposed within a reaction gas, wherein the reaction gas comprises one or more of oxygen, hydrogen, nitrogen, or combinations thereof.

10. A method of making a semiconductor device comprising:
depositing a flowable layer of silicon containing material over one or more features over a substrate; and
implanting oxygen radicals substantially throughout the flowable layer of silicon containing material to anneal and increase a density of the flowable layer of silicon containing material.

11. The method of claim 10, wherein the flowable layer of silicon containing material comprises an oxide layer, a nitride layer, a carbide layer, an oxynitride layer, or combinations thereof.

12. The method of claim 10, wherein the flowable layer of silicon containing material comprises silicon oxide (SiO₂), silicon oxide nitride (SiON), silicon nitride (Si₃N₄), silicon oxide carbide (SiOC), or combinations thereof.

13. The method of claim 10, wherein implanting oxygen radicals is performed at a pressure of 10 mTorr to 20 Torr.

14. The method of claim 10, wherein implanting oxygen radicals is performed at a temperature of 100 degrees Celsius to 700 degrees Celsius.

15. The method of claim 10, wherein implanting oxygen radicals is performed for a duration of up to 10 minutes.

16. The method of claim 10, wherein the oxygen radicals penetrate entirely throughout the flowable layer of silicon containing material.

17. The method of claim 10, wherein implanting oxygen radicals into a flowable layer of silicon containing material is performed in a rapid thermal processing chamber.

18. The method of claim 10, wherein prior to implanting oxygen radicals into a flowable layer of silicon containing material the flowable layer of silicon containing material is contacted with ozone and water.

19. An apparatus to manufacture an electronic device comprising:
a processing chamber comprising a pedestal to hold a substrate comprising a flowable layer of silicon containing material over the substrate;
an oxygen radical source coupled to the processing chamber; and
a processor coupled to the processing chamber and oxygen radical source, wherein the processor is configured to provide conditions in the processing chamber sufficient to anneal and increase a density of the flowable layer of silicon containing material.

20. The apparatus of claim 19, wherein the flowable layer of silicon containing material comprises silicon oxide (SiO₂), silicon oxide nitride (SiON), silicon nitride (Si₃N₄), silicon oxide carbide (SiOC), or combinations thereof, and wherein the conditions comprise a pressure of 10 mTorr to 20 Torr, a temperature of 100 degrees Celsius to 700 degrees Celsius for a duration of up to 10 minutes.
